(19) United States
(12) Patent Application Publication
(10) Pub. No.: US 2025/0364283 A1
(43) Pub. Date: Nov. 27, 2025

(54) APPARATUS FOR TREATING A SUBSTRATE AND METHOD FOR TREATING A SUBSTRATE

(71) Applicant: SEMES CO., LTD., Cheonan-si (KR)

(72) Inventors: Seul Gi CHOI, Busan (KR); Eun Jung LEE, Seoul (KR); Jun Hyun LIM, Seoul (KR); Hee Jun YOUN, Goyang-si (KR)

(73) Assignee: SEMES CO., LTD., Cheonan-si (KR)

(21) Appl. No.: 19/215,629

(22) Filed: May 22, 2025

(30) Foreign Application Priority Data
May 22, 2024 (KR) 10-2024-0066198

(51) Int. Cl. H01L 21/67; H01L 21/677

(52) U.S. Cl. CPC H01L 21/67167; H01L 21/67034; H01L 21/67057; H01L 21/67718

(57) ABSTRACT

The apparatus includes a first processing unit having a batch processing bath that processes a plurality of substrates in a vertical posture in a batch; a second processing unit adjacent to the first processing unit; and a transfer unit transferring the plurality of substrates in the vertical posture between the first and second processing unit, wherein the second processing unit includes a transfer chamber; a plurality of process chamber disposed around the transfer chamber and processing substrates in a horizontal posture one by one; a first buffer bath disposed in the transfer chamber and providing an accommodation space in which a plurality of substrates in a vertical posture stands by while being immersed in a processing solution; a first transfer robot changing the substrates disposed in the first buffer bath from the vertical posture to the horizontal posture, and transferring substrates between the first buffer bath and the process chambers.

### CROSS-REFERENCE TO RELATED APPLICATIONS

This application claims priority to and the benefit of Korean Patent Application No. 10-2024-0066198 filed in the Korean Intellectual Property Office on May 22, 2024, the entire contents of which are incorporated herein by reference.

### TECHNICAL FIELD

The present disclosure relates to an apparatus for treating a substrate and a method for treating a substrate.

### BACKGROUND ART

In order to manufacture a semiconductor device, a desired pattern is formed on a substrate such as a wafer through various processes such as photolithography, etching, ashing, ion implantation, and thin film deposition. Various processing solutions and processing gases are used in each of the processes, and particles and process byproducts are generated during the processes. Liquid processing is performed on a substrate before and after each process to remove a thin film, particles, and process byproducts from the substrate. In general, liquid processing processes a substrate with a chemical, and then removes the chemical on the substrate with a rinse solution and then performs drying.

As a method of processing substrates with a processing solution such as a chemical and/or a rinse solution, there is a batch-type processing method that processes a plurality of substrates in a vertical posture in a batch. The batch-type processing method processes substrates by immersing a plurality of substrates in a vertical posture in a batch in a processing bath containing a chemical or a rinse solution. On the other hand, in the case of a single-wafer processing method in which substrates are processed one by one, substrate processing is performed by supplying a chemical or a rinse solution to a single substrate rotating in a horizontal posture.

Recently, apparatuses that are equipped with both a batch-type processing unit and a single-wafer processing unit in a single apparatus and can process substrates in a batch type and then in a single-wafer type are used. When a substrate processing apparatus is equipped with both a batch-type processing unit and a single-wafer processing unit, it is essential to change the posture of substrates from a vertical posture to a horizontal posture. In the process of transferring substrates processed in a batch-type processing unit to a single-wafer processing unit while changing the posture of the substrates, pattern leaning may occur on the pattern formed on the substrates. Further, when a plurality of substrates, which have undergone batch-type processing, is exposed to air for a long time in a vertical or horizontal posture, there is a risk that water marks may form on the substrates due to the loss of wettability.

### SUMMARY OF THE INVENTION

An objective of the present invention is to provide an apparatus for treating a substrate and a method for treating a substrate, the apparatus and method being able to improve mass production capability in substrate processing.

Further, an objective of the present invention is to provide an apparatus for treating a substrate and a method for treating a substrate, the apparatus and method being able to minimize the risk of water marks forming on substrates.

Further, an objective of the present invention is to provide an apparatus for treating a substrate and a method for treating a substrate, the apparatus and method being able to minimize occurrence of pattern leaning on the pattern formed on substrates.

Further, an objective of the present invention is to provide an apparatus for treating a substrate and a method for treating a substrate, the apparatus and method being able to minimize contamination of a substrate transfer unit by contaminants such as particles remaining on substrates during a substrate transfer process, and prevent contamination of substrates.

The objectives of the present disclosure are not limited thereto and other objectives not stated herein may be clearly understood by those skilled in the art from the following description.

An exemplary embodiment of the present disclosure, an apparatus for treating a substrate, comprising: a first processing unit having a batch processing bath that processes a plurality of substrates in a vertical posture in a batch; a second processing unit disposed adjacent to the first processing unit; and a transfer unit transferring the plurality of substrates in the vertical posture between the first processing unit and the second processing unit, wherein the second processing unit may include: a transfer chamber; a plurality of process chambers disposed around the transfer chamber and processing substrates in a horizontal posture one by one; a first buffer bath disposed in the transfer chamber and providing an accommodation space in which a plurality of substrates in a vertical posture stands by while being immersed in a processing solution; a first transfer robot changing the substrates disposed in the first buffer bath from the vertical posture to the horizontal posture, and transferring substrates between the first buffer bath and the process chambers.

According to an embodiment of the present disclosure, the second processing unit may include, a second buffer bath disposed in the transfer chamber and storing substrates processed in the process chambers in a vertical posture; and a second transfer robot unloading substrates processed in the process chambers, changing the substrates from the horizontal posture to the vertical posture, and transferring the substrates to the second buffer bath.

According to an embodiment of the present disclosure, the batch processing bath and the first buffer bath are arranged side by side in a first direction, and the transfer unit may transfers a plurality of substrates between the batch processing bath and the first buffer bath.

According to an embodiment of the present disclosure, the processing chamber may include a liquid processing chamber and a drying chamber.

According to an embodiment of the present disclosure, the posture change of the substrates from the vertical posture to the horizontal posture by the first transfer robot may be performed with the substrates immersed in a processing solution retained in the accommodation space of the first buffer bath.

According to an embodiment of the present disclosure, the first processing unit, the first buffer bath, and the second buffer bath are sequentially arranged in the first direction, and the first transfer robot and the second transfer robot may be disposed between the first buffer bath and the second buffer bath.

According to an embodiment of the present disclosure, the first transfer robot and the second transfer robot may be arranged in a second direction perpendicular to the first direction.

According to an embodiment of the present disclosure, a hand of the first transfer robot and a hand of the second transfer robot may be provided at different heights.

According to an embodiment of the present disclosure, the process chambers may be provided in a polygonal shape when viewed from above.

According to an embodiment of the present disclosure, the controller may further include the controller controls the first transfer robot to change the substrates disposed in the first buffer bath from the vertical posture to the horizontal posture and transfer the substrates to the liquid processing chamber.

According to an embodiment of the present disclosure, the controller may controls the first transfer robot to unload the substrates liquid-processed in the liquid processing chamber and transfer the substrates to the drying chamber.

According to an embodiment of the present disclosure, the controller may controls the second transfer robot to unload the substrates dried in the drying chamber, change the posture of the substrates from the horizontal posture to the vertical posture, and transfer the substrates to the second buffer bath.

An exemplary embodiment of the present disclosure, a method for treating a substrate using the apparatus of claim 1, wherein the method performs a first processing of processing a plurality of substrates in a vertical posture in a batch; transfers the plurality of substrates to the first buffer bath using the transfer unit; and performs a second processing of processing the substrates one by one, wherein the second processing changes the substrates from the vertical posture to the horizontal posture and transfers the substrates to the process chambers using the first transfer robot; performs the second processing of processing the substrates in the horizontal posture one by one using the processing chambers; and unloads the substrates processed in the process chambers, change the posture of the substrates from the horizontal posture to the vertical posture, and may transfers the substrates to the second buffer bath using the second transfer robot.

According to an embodiment of the present disclosure, the first transfer robot may changes the posture of the substrates while the substrates are immersed in a processing solution.

According to an embodiment of the present disclosure, wherein the second processing changes the substrates from the vertical posture to the horizontal posture and transfers the substrates to the liquid processing chamber using the first transfer robot; performs liquid processing on the substrates in the horizontal posture using the liquid processing chamber; unloads the liquid-processed substrates from the liquid processing chamber and transfers the substrates to the drying chamber using the first transfer robot; and unloads the substrates dried in the drying chamber, changes the posture of the substrates from the horizontal posture to the vertical posture, and may transfers the substrates to the second buffer bath using the second transfer robot.

According to an embodiment of the present disclosure, the first transfer robot includes a plurality of hands, and a hand used by the first transfer robot to transfer the substrates to the liquid processing chamber and a hand used by the first transfer robot to transfer the liquid-processed substrates from the liquid processing chamber to the drying chamber may be different.

An exemplary embodiment of the present disclosure, an apparatus for treating a substrate, comprising: a first processing unit having a batch processing bath that processes a plurality of substrates in a vertical posture in a batch; a second processing unit disposed adjacent to the first processing unit; and a transfer unit transferring the plurality of substrates in the vertical posture between the first processing unit and the second processing unit while moving in a first direction, wherein the second processing unit includes: a transfer chamber; a plurality of process chamber disposed around the transfer chamber and processing substrates in a horizontal posture one by one; a first buffer bath disposed in the transfer chamber and providing an accommodation space in which a plurality of substrates in a vertical posture stands by while being immersed in a processing solution; a first transfer robot changing the substrates disposed in the first buffer bath from the vertical posture to the horizontal posture, and transferring substrates between the first buffer bath and the process chambers; a second buffer bath disposed in the transfer chamber and storing substrates processed in the process chambers in a vertical posture; and a second transfer robot unloading substrates processed in the process chambers, changing the substrates from the horizontal posture to the vertical posture, and transferring the substrates to the second buffer bath, the processing chambers include a liquid processing chamber and a drying chamber, the first processing unit, the first buffer bath, and the second buffer bath are sequentially arranged in the first direction, and the first transfer robot and the second transfer robot may be disposed between the first buffer bath and the second buffer bath.

According to an embodiment of the present disclosure, the posture change of the substrates from the vertical posture to the horizontal posture by the first transfer robot may be performed with the substrates immersed in a processing solution retained in the accommodation space of the first buffer bath.

According to an embodiment of the present disclosure, a hand of the first transfer robot and a hand of the second transfer robot may be provided at different heights.

According to an embodiment of the present disclosure, the controller may further include the controller controls the first transfer robot to change the substrates disposed in the first buffer bath from the vertical posture to the horizontal posture and transfer the substrates to the liquid processing chamber, controls the first transfer robot to unload the substrates liquid-processed in the liquid processing chamber and transfer the substrates to the drying chamber, and controls the second transfer robot to unload the substrates dried in the drying chamber, change the posture of the substrates from the horizontal posture to the vertical posture, and transfer the substrates to the second buffer bath.

According to an embodiment of the present disclosure, it is possible to improve mass productivity in substrate processing.

Further, according to an embodiment of the present disclosure, it is possible to minimize the risk of water marks forming on substrates.

Further, according to an embodiment of the present disclosure, it is possible to minimize the occurrence of leaning on a pattern formed on substrates.

Further, according to an embodiment of the present disclosure, it is possible to minimize reverse contamination of transfer units due to contaminants such as particles remaining on substrates and prevent contamination of substrates in a transfer process. Effects of the present disclosure are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a schematic view of an apparatus for treating a substrate according to an embodiment of the present disclosure, viewed from above.

FIG. 2 is a view schematically showing the structure of a first buffer bath of FIG. 1.

FIG. 3 is a view schematically showing the appearance of a first transfer robot of FIG. 1.

FIG. 4 is a view showing the appearance of an apparatus for treating a substrate provided to a liquid processing chamber of FIG. 1.

FIG. 5 is a view showing the appearance of an apparatus for treating a substrate provided to a drying chamber of FIG. 1.

FIG. 6 is a flowchart showing a method for treating a substrate according to an embodiment of the present disclosure.

FIG. 7 is a view showing the state in which the first transfer robot of FIG. 1 changes the posture of substrates from a vertical posture to a horizontal posture.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Further, components that transfer substrates W to be described below, for example, transfer units or transfer robots may be referred to as transfer modules.

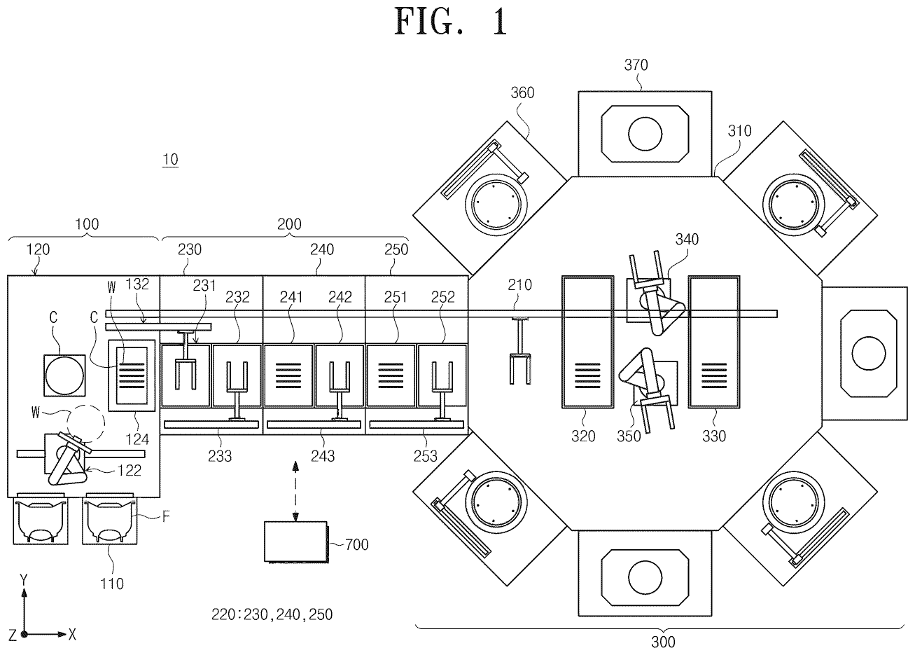

Hereafter, embodiments of the present disclosure are described with reference to FIG. 1 to FIG. 7.

FIG. 1 is a schematic view of an apparatus for treating a substrate according to an embodiment of the present disclosure, viewed from above.

Referring to FIG. 1, an apparatus for treating a substrate according to an embodiment of the present disclosure may include an index module 100, a first processing unit 200, a second processing unit 300, and a controller 700. The index module 100, the first processing unit 200, and the second processing unit 300 may be arranged in a first direction X when viewed from above. Hereafter, a direction perpendicular to the first direction X when viewed from above is referred to as a second direction Y, and a direction perpendicular to both the first direction X and the second direction Y is referred to as a third direction Z.

The index module 100 may include a load port unit 110, an index chamber 120, and an index transfer unit 132.

The load port unit 110 may include at least one or more load ports. A transfer container F in which a substrate W is accommodated may be placed in the load ports of the load port unit 110. A plurality of substrates W may be accommodated in the transfer container F. For example, 25 substrates W may be accommodated in the transfer container F. The transfer container F may be referred to as a cassette, a FOD, or a FOUP. The transfer container F can be loaded or unloaded onto or from the load port unit 110 by a container transfer device.

The substrates W accommodated in the transfer containers F that are placed on some load ports of a plurality of load ports may be unprocessed substrates W. The unprocessed substrates W may be substrates W that have not been processed, or substrates W that have been partially processed but require liquid processing. The substrates W accommodated in the transfer containers F that are placed on the other load ports of the plurality of load ports may be substrates W that have been processed by the first processing unit 200 and the second processing unit 400. That is, some load ports of the plurality of load ports may serve to load unprocessed substrates W that require processing, and the remaining load ports of the plurality may serve to unload processed substrates W from the apparatus 10 for treating a substrate. For example, referring to FIG. 1, the load port unit 110 may include two load ports, in which one load port of the two load ports may be provided as a first load port unit on which unprocessed substrates W are loaded, and the other one load port may be provided as a second load port unit from which processed substrates W are unloaded. Although the this specification illustrates an example in which the number of load ports is two, the number is not limited thereto and may vary depending on factors such as process efficiency or footprint.

The index chamber 120 may be coupled to the load port unit 110. The index chamber 120 and the load port unit 110 may be arranged in the second direction Y. The index chamber 120 may include an index robot 122 and a posture changing unit 124. The index robot 122 can unload unprocessed or processing-required substrates W from the container F seated on the load port unit 110. The index robot 122 can transfer substrates W from the container F and load them into an accommodation container C. The index robot 122 can transfer the processed substrates W to the container F seated on the load port unit 110. The index robot 122 can transfer the substrates W processed and stored in a buffer unit (not shown) to the container F that is placed on the load port. The index robot 122 can load the processed substrates W into the container F placed on the load port included the second load port unit of the load port units 110. The container F can be transferred to the outside of the apparatus for treating a substrate by a product transfer device (e.g., OHT).

The index robot 122 may have a hand that can hold and transfer substrates W. The index robot 122 may have a plurality of hands, some of which can be used solely for transferring substrates W from the container F to an accommodation container C, and others of which can be used solely for transferring processed substrates W from the buffer unit (not shown) to the container F. The hand of the index robot 122 may be a single-wafer hand that transfers substrates W one by one. The hand of the index robot 122 may be provided to be able to move in the first direction X, the second direction Y, and the third direction Z. Further, the hand of the index robot 122 may be provided to be rotatable around the third direction Z.

The accommodation container C may substantially have a box shape. The accommodation container C may have an accommodation space therein. A plurality of substrates W may be accommodated in the accommodation space of the accommodation container C. For example, 50 substrates W may be accommodated in the accommodation space of the accommodation container C. The accommodation container C may have a box shape of which at least two or more surfaces of the surfaces thereof are open. A supporting member that supports/holds substrates W may be provided in the accommodation space of the accommodation container C.

When substrates W unloaded from the transfer container F finish being loaded into the accommodation container C, the substrates W can be transferred to the posture changing unit 124 disposed in the index chamber 120 by a transfer part not shown. The posture changing unit 124 can rotate the accommodation container C. For example, the posture changing unit 124 can rotate the accommodation container C such that an open portion of the accommodation container C faces up. When the accommodation container C is rotated such that an open portion faces up, the posture of the substrates W accommodated in the accommodation container C can be changed from a horizontal posture (posture with the top side and the bottom side of the substrates W parallel with the ground) to a vertical posture. The horizontal posture may mean that the top side of a substrate (for example, a surface with a pattern) is parallel with an X-Y plane (i.e., the ground) and the vertical position may mean that the top side of a substrate W is parallel with an X-Z plane or a Y-Z plane (i.e., a surface perpendicular to the ground).

The index transfer unit 132 can transfer substrates W between the index chamber 120 and the first processing unit 200. The index transfer unit 132 can hold substrates W with the posture changed at the posture changing unit 124 and transfer the held substrates W to a batch processing unit 220. For example, the index transfer unit 132 can transfer substrates W with the posture changed at the posture changing unit 124 to any one processing bath selected from the processing baths of the processing units 230, 240, and 250 included in the batch processing unit. For example, the index transfer unit 132 can transfer substrates W with the posture changed at the posture changing unit 124 to a 1-1 batch processing bath 231 of a first batch processing unit 230.

The first processing unit 200 can perform liquid processing on a plurality of substrates W all at once in a batch type. For example, the first processing unit 200 can perform cleaning on a plurality of substrates W all at once in a batch type. The first processing unit 200 can simultaneously process a plurality of substrates W in a vertical posture (posture with the top surface and bottom surface of substrates perpendicular to the ground).

The first processing unit 200 may include a batch transfer unit 210 and a batch processing unit 220.

The batch transfer unit 210 may include a rail extending in the first direction X and a hand configured to be able to transfer a plurality of substrates W at a time.

The batch transfer unit 210 may be configured to be able to transfer substrates W among a first batch processing unit 230, a second batch processing unit 240, and a third batch processing unit 250 of the batch processing unit 220. Further, the batch transfer unit 210 may be configured to be able to transfer substrates W between the first processing unit 200 and the second processing unit 300. The batch transfer unit 210 may be configured to be able to transfer substrates W processed at the batch processing unit 220 and arranged in a vertical posture to a first buffer bath 320 provided in the transfer chamber 310 of the second processing unit 300. The batch transfer unit 210 is provided as a batch transfer unit that transfers a plurality of substrates in a vertical posture in a batch.

Further, substrates W changed in posture by the posture changing unit 124 and accommodated in the accommodation container C and substrates W accommodated in the batch processing bath of the batch processing unit 220 may be arranged side by side in the first direction when viewed from above.

The batch processing unit 220 can perform liquid processing on a plurality of substrates W at a time. The batch processing unit 220 can perform cleaning on a plurality of substrates W at a time using a processing solution. The batch processing unit 220 can perform liquid processing on a plurality of substrates W at a time using a processing solution. The processing solution that is used in the batch processing unit 220 may be a chemical and/or a rinse solution. For example, the chemical may be a chemical that has the property of strong acid or strong base. Further, the rinse solution may be pure water. For example, the chemical may be appropriately selected from Ammonia-Hydrogen Peroxide Mixture (APM), Hydrochloricacid-Hydrogen Peroxide Mixture (HPM), Hydrofluoricacid-Hydrogen Peroxide Mixture (FPM), Diluted Hydrofluoric acid (DHF), Diluted Sulfuric acid Peroxide (DSP), chemical removing SiN, chemical containing phosphoric acid, chemical containing sulfuric acid, or the like. The rinse solution may be a solution containing water. For example, the rinse solution may be appropriately selected from pure water or ozonated water.

The batch processing unit 220 may include a first batch processing unit 230, a second batch processing unit 240, and a third batch processing unit 250.

The first batch processing unit 230 may include a 1-1 batch processing bath 231, a 1-2 batch processing bath 232, and a first batch transfer unit 233.

It is possible to simultaneously perform liquid processing on a plurality of substrates W with a chemical such as DSP in the 1-1 batch processing bath 231. It is possible to simultaneously perform liquid processing on a plurality of substrates W with a chemical such as DHF in the 1-2 batch processing bath 232. However, the present disclosure is not limited thereto, and the processing solution used in the 1-1 batch processing bath 231 and the 1-2 batch processing bath 232 may be changed to a processing solution selected from the processing solutions described above.

The first batch transfer unit 141c may be configured to be able to transfer substrates W between 1-1 batch processing bath 231 and the 1-2 batch processing bath 232.

The second batch processing unit 142 may include a 2-1 batch processing bath 241, a 2-2 batch processing bath 242, and a second batch transfer unit 243.

It is possible to simultaneously perform liquid processing on a plurality of substrates W with a chemical containing phosphoric acid in the 2-1 batch processing bath 241. It is possible to simultaneously process a plurality of substrates W with a rinse solution in the 2-2 batch processing bath 242. However, the present disclosure is not limited thereto, and the processing solution used in the 2-1 batch processing bath 241 and the 2-2 batch processing bath 242 may be changed to a processing solution selected from the processing solutions described above.

The second batch transfer unit 243 may be configured to be able to transfer substrates W between the 2-1 batch processing bath 241 and the 2-2 batch processing bath 242.

The third batch processing unit 143 may include a 3-1 batch processing bath 251, a 3-2 batch processing bath 252, and a third batch transfer unit 253.

It is possible to simultaneously perform liquid processing on a plurality of substrates W with a chemical containing phosphoric acid in the 3-1 batch processing bath 251. It is possible to simultaneously process a plurality of substrates W with a rinse solution in the 3-2 batch processing bath 252. However, the present disclosure is not limited thereto, and the processing solution used in the 3-1 batch processing bath 251 and the 3-2 batch processing bath 252 may be changed to a processing solution selected from the processing solutions described above.

The third batch transfer unit 253 may be configured to be able to transfer substrates W between the 3-1 batch processing bath 251 and the 3-2 batch processing bath 252. The second processing unit 200 can process the substrates W processed at the first processing unit 100. The second processing unit 200 can perform liquid processing and drying on the substrates W processed at the first processing unit 100 and a single-wafer type.

The second processing unit 200 is disposed adjacent to the first processing unit 200.

The second processing unit 200 may include a transfer chamber 310, a first buffer bath 320, a second buffer bath 330, a first transfer robot 340, a second transfer robot 350, a liquid processing chamber 360, and a drying chamber 370. The liquid processing chamber 360 and the drying chamber 370 both may be referred to as a single-wafer processing chamber.

The transfer chamber 310 can store substrates W transferred from the first processing unit 200 in a standby state. The transfer chamber 310 can store substrates W processed at the second processing unit 200 in a standby state. In the transfer chamber 310, substrates W in a vertical posture can be changed to a horizontal posture, or substrates Win a horizontal posture can be changed to a vertical posture. The posture changing unit 310 can change the posture of the substrates W changed to a vertical posture at the batch processing unit 220 such that the substrates W can be post-processed in the single-wafer processing chambers 360 and 370 that process substrates W one by one in a horizontal posture. In the transfer chamber 310, the posture of substrates W processed at the single-wafer processing chambers 360 and 370 can be changed such that the substrates can be stored in a vertical posture. The posture changing of substrates W is described below.

A plurality of processing chambers is arranged around the transfer chamber 310. The processing chamber may be a chamber that processes substrates W one by one. That is, the processing chamber may be a chamber that performs a process of processing substrates W in a single-wafer type. The processing chamber may be the liquid processing chamber 360 and/or the drying chamber 370. According to an embodiment, the transfer chamber 310 is provided in a polygonal shape when viewed from above, and one processing chamber may be disposed per side of the polygon. The processing chambers arranged at the sides of the polygon, respectively, may be stacked in a plurality of layers, and thus a plurality of processing chambers may be stacked and arranged around the transfer chamber 310.

The first buffer bath 320, the second buffer bath 330, the first transfer robot 340, and the second transfer robot 350 are arranged in the internal space of the transfer chamber 310. The first processing unit 200, the first buffer bath 320, and the second buffer bath 330 are sequentially arranged in the first direction X, and the first transfer robot 340 and the second transfer robot 350 are arranged between the first buffer bath 320 and the second buffer bath 330. The first transfer robot 340 and the second transfer robot 350 may be arranged in the second direction Y.

Substrates W transferred after being processed in the batch processing unit 220 are stored in the first buffer bath 320. The batch transfer unit 210 transfers a plurality of substrates W processed at the batch processing unit 220 and arranged in a vertical posture to the first buffer bath 320 provided in the transfer chamber 310 of the second processing unit 300.

The first buffer bath 320 may have a larger width than the batch processing baths 231 to 252 when viewed from above. For example, the first buffer bath 320 may have a larger width in the second direction Y (one direction) than the batch processing baths 231 to 252 provided to the batch processing unit 220 when viewed from above.

The first buffer bath 320 may be positioned adjacent to the first processing unit 200.

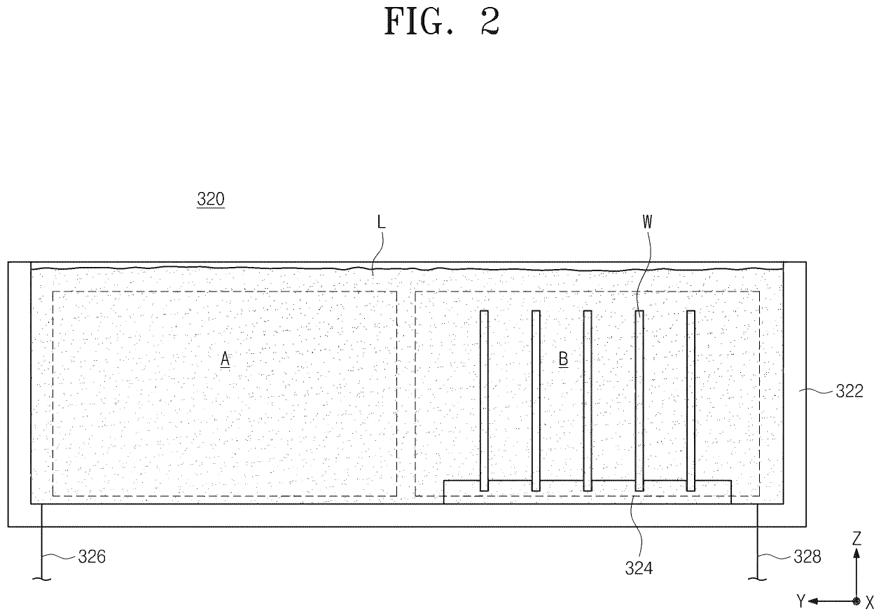

FIG. 2 is a view schematically showing the structure of a first buffer bath of FIG. 1. Referring to FIG. 2, the first buffer bath 320 may include a processing bath 322, a supporting member 324, a supply line 326, and a return line 318.

The processing bath 322 may have a box shape with an open top. The processing bath 322 may have a rectangular box shape with an open top. The processing bath 322 may have an accommodation space A, B in which a processing solution L can be accommodated (retained). The processing solution L retained in the processing bath 322 may be a solution containing water.

The supporting member 324 is disposed in the accommodation space A, B and can support substrates W. The supporting member 324 may be configured to be able to support a plurality of substrates W. For example, the supporting member 324 may be configured to be able to support 50 substrates W. The supporting member 324 may be configured such that a pair of rod-shaped bodies is disposed to face each other and a supporting groove (not shown) in which a substrate W can be supported is formed at each of the bodies.

The supply line 326 can supply a processing solution L to the accommodation space A, B. The return line 328 can drain the processing solution L from the accommodation space A, B. Both the supply line 326 and the return line 328 are equipped with valves, and on the basis of the liquid level of the processing solution L sensed by a liquid level sensor not shown, the level of the processing solution L supplied to the accommodation space A, B (that is, the amount of the processing solution L retained in the accommodation space A, B) can be adjusted to a set level.

Further, the accommodation space A, B may include a support area A and a posture changing area B. The support area A may be the area in which the supporting member 324 supports substrates W. The support area A may be a space in which substrates W stand by in a supported state on the support member 324. The posture changing area B may be an area in which the posture of substrates W is changed by the first transfer robot 340 to be described below.

Referring to FIG. 1 again, the support area A of the first buffer bath 320 and the batch processing baths in the batch processing unit 220 may be arranged in the first direction X.

The area in which substrates W are accommodated in the batch processing baths 231 to 252 of the batch processing unit 220 and the support area of the first buffer bath 320 in which substrates W are accommodated may be arranged side by side in the first direction. Accordingly, while substrates W are transferred from the first processing unit 200 to the first buffer bath 320, the substrates W can be moved only in the first direction X without being moved in the second direction Y. Accordingly, the time for which wet-state substrates W are exposed to the air in a vertical position while they are transferred from the first processing unit 200 to the first buffer bath 320 can be minimized. Accordingly, it is possible to minimize the occurrence of pattern leaning and water marks on substrates during a transfer process.

Substrates W processed in the processing chambers 360 and 370 are stored in the second buffer bath 330. Since any processing solution is not retained in the second buffer bath 330, substrates W can be stored in a dried state. Substrates W can be stored in a vertical posture in the second buffer bath 330. The second buffer bath 330 may include a configuration similar to the supporting member 324 of the first buffer bath 320.

The first transfer robot 340 may be disposed at one side of the first buffer bath 320. The first transfer robot 340 may be disposed between the first buffer bath 320 and the second buffer bath 330. The first transfer robot 340 may be a transfer robot that transfers wet-state substrates W. The first transfer robot 340 can change the posture of substrates W from a vertical posture to a horizontal posture in the first buffer bath 320, and transfer the wet-state substrates W changed into a horizontal posture to a processing chamber to be described below, for example, the liquid processing chamber 360. Further, as will be described below, the first transfer robot 340 can unload the wet-state substrate W processed in the liquid processing chamber 360, and transfer them to the drying chamber 370.

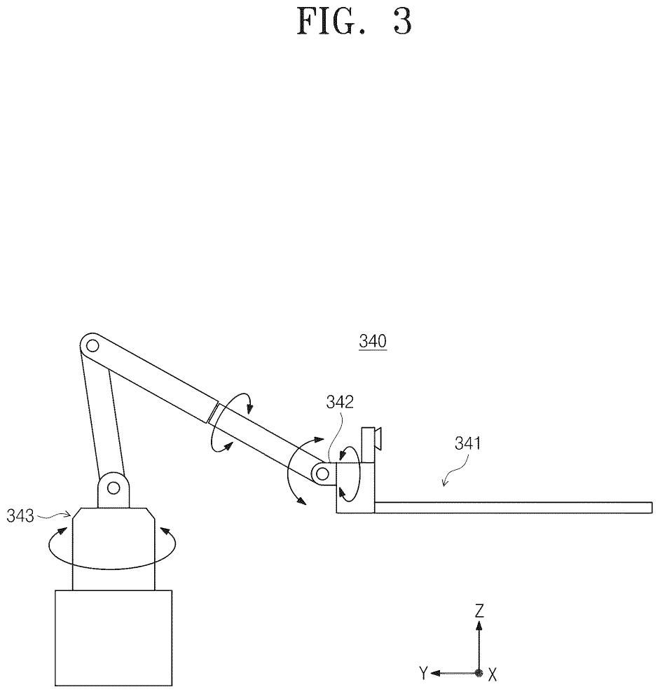

FIG. 3 is a view schematically showing the appearance of a first transfer robot of FIG. 1.

Referring to FIG. 1 to FIG. 3, the first transfer robot 340 may include a hand 341, a rotary shaft 342, and a joint part 343. The hand 341 may be coupled to the joint part 343 through the rotary shaft 342. The joint part 343 can change the position of the hand 341.

Further, the first transfer robot 340 may be an articulated robot. The first transfer robot 340 may be a 6-axis articulated robot.

The joint part 343 may be an articulated arm composed of at least two or more axes. For example, the joint part 343 may be a 6-axis articulated arm. The joint part 343 can change the position of the hand 341 by moving the hand 341 in at least one or more directions of the first direction X, the second direction Y, and the third direction Z. Further, the joint part 343 can rotate the hand 341 with respect to one axis of the axes of the first direction X, the second direction Y, and the third direction Z.

The second transfer robot 350 may be disposed at one side of the first buffer bath 320. The second transfer robot 350 may be disposed between the first buffer bath 320 and the second buffer bath 330. The second transfer robot 350 may be a transfer robot that transfers dry-state substrates W. The second transfer robot 350 can unload dry-state substrates W dried in the drying chamber 360, change the posture of the substrates W from a horizontal posture to a vertical posture, and store them in the second buffer bath 330. Since the structure of the second transfer robot 350 is the same as that of the first transfer robot 340, a detailed description thereof is omitted.

The first transfer robot 340 and the second transfer robot 350 may be disposed such that the hands 341 of the first transfer robot 340 and the second transfer robot 350 do not interfere with each other during rotation. The hands 341 of the first transfer robot 340 and the second transfer robot 350 may be provided at different heights. The first transfer robot 340 and the second transfer robot 350 may be installed at different heights.

Although the first transfer robot 340 and the second transfer robot 350 are shown and described as having one hand 341 in the example described above, the first transfer robot 340 and the second transfer robot 350 may have a plurality of hands 341. For example, the first transfer robot 340 may be equipped with a plurality of hands 341, some of which are used to change the posture of substrates W and transfer them to the liquid processing chamber 360, while the others are used to unload processed substrates W from the liquid processing chamber 360 and transfer them to the drying chamber 370. In other words, the hands used by the first transfer robot 340 to transfer substrates W to the liquid processing chamber 360 and the hands used to transfer substrates W from the liquid processing chamber 360 to the drying chamber 370 may be different. By distinguishing between the hands used to transfer substrates W to the liquid processing chamber 360 and the hands used to transfer substrates to the drying chamber 370, as described above, it is possible to minimize contamination of the transfer unit due contaminants such as particles remaining on substrates W and prevent contamination of the substrates W during a transfer process.

A plurality of liquid processing chambers 360 may be provided. A plurality of liquid processing chambers 360 may be provided around the transfer chamber 310 and may be stacked in the vertical direction. The liquid processing chamber 360 can rotate the posture of substrates W and can process the substrates W by supplying a processing solution to the rotating substrates W. Substrates W can be processed one by one in the liquid processing chamber 360. The processing solution that is supplied in the liquid processing chamber 360 may be an organic solvent. For example, the processing solution that is supplied in the liquid processing chamber 360 may be isopropyl alcohol (IPA). In the liquid processing chamber 360, it is possible to supply an organic solvent to rotating substrates W and dry the substrates W by rotating the substrates W. Unlike, an organic solvent is supplied to rotating substrates W in the liquid processing chamber 360, the substrates W are transferred to the drying chamber 370 to be described below in the wet state by the organic solvent, and the substrates W can be dried in the drying chamber 370. The liquid processing chamber 360 is described in detail below.

A plurality of drying chambers 370 may be provided. A plurality of drying chambers 370 may be provided around the transfer chamber 310 and may be stacked in the vertical direction. Substrates W can be processed in the drying chamber 370 using a supercritical liquid. The drying chamber 370 may be a supercritical chamber that dries one substrate W in a single-wafer type. The drying chamber 370 may be a supercritical chamber that dries a substrate W using a supercritical fluid. The drying chamber 370 is described in detail below.

A controller 700 can control the apparatus 10 for treating a substrate. For example, the controller 700 can control the components of the apparatus 10 for treating a substrate. For example, the controller 700 can control the apparatus 10 for treating a substrate such that the apparatus 10 for treating a substrate can perform a process of processing substrates W.

Further, the controller 700 may include: a process controller that is a microprocessor (computer) that performs control of the apparatus 10 for treating a substrate; a user interface that is a keyboard through which an operator performs command input operation, etc. to manage the apparatus 10 for treating a substrate, a display that visualizes and displays the operation situation of the apparatus 10 for treating a substrate, etc.; and a memory that stores a control program for processing, which is performed in the apparatus 10 for treating a substrate, under control of the process controller, a program for processing each component in accordance with various data and processing conditions, that is, a treatment recipe. Further, the user interface and the memory may be connected to the process controller. The processing recipe may be stored in a memory medium of the memory and the memory medium may be a hard disk and may be a portable disc, such as a CD-ROM and a DVD, or a semiconductor memory such as a flash memory.

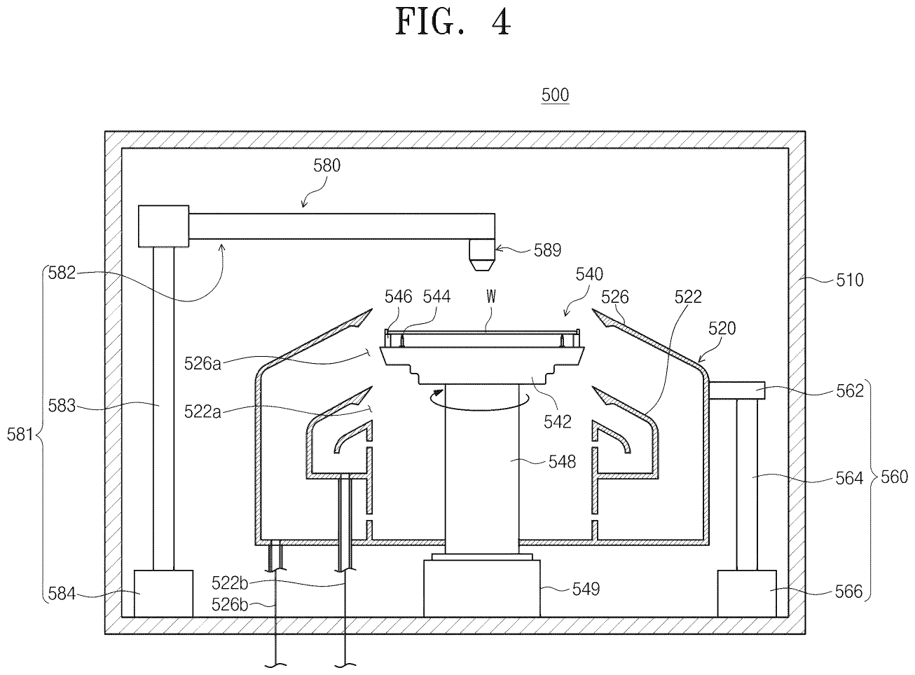

FIG. 4 is a view showing the appearance of an apparatus for treating a substrate provided to a liquid processing chamber of FIG. 1.

Referring to FIG. 4, an apparatus 500 for treating a substrate provided to the liquid processing chamber 360 includes a housing 510, a processing container 520, a supporting unit 540, a lifting unit 560, a liquid supply unit 580.

The housing 510 has a processing space 512 therein. The housing 510 may have a cylindrical shape with a space therein. The processing container 520, the supporting unit 540, the lifting unit 560, the liquid supply unit 580 may be provided in the internal space 512 of the housing 510. The housing 510 may have a rectangular shape when viewed from the front. However, the present disclosure is not limited thereto and the housing 510 may be modified in various shapes that can have the processing space 512.

The processing container 520 has a cylindrical shape with an open top. The processing container 520 has an internal collection tank 522 and an outer collection tank 526. The collection tank 322 and 326 collect different processing solutions from solutions used in a process. The inner collection tank 522 is provided in a ring shape surrounding the substrate supporting unit 540 and the outer collection tank 526 is provided in a ring shape surrounding the inner collection tank 522. The internal space 522a of the inner collection tank 522 and the inner collection tank function as a first inlet 522a through which a processing solution flows into the inner collection tank 522. The space 526a between the inner collection tank 522 and the outer collection tank 526 functions as a second inlet 526a through which a processing solution flows into the outer collection tank 526. According to an embodiment, the inlets 522a and 426a may be positioned at different heights. Return lines 522b and 426b are connected to the undersides of the collection tanks 522 and 426, respectively. Processing solutions flowing in the collection tanks 522 and 426 can be provided to a processing solution recycle system (not shown) at the outside through the return lines 522b and 426b and can be reused.

The supporting unit 540 supports substrates W in the processing space 512. The supporting unit 540 supports and rotates substrates W in during a process. The supporting unit 540 has a supporting plate 542, a supporting pin 544, a chuck pin 546, and a rotating unit 548, 549. The supporting plate 542 is provided substantially in a circular disc shape and has an upper surface and a lower surface. The lower surface has a smaller diameter than the upper surface. That is, the supporting plate 542 may have a reverse trapezoidal shape with a wide upper surface and a narrow lower surface. The upper surface and the lower surface are positioned such that the center axes coincide with each other. Further, the supporting plate 5432 may be equipped with a heating unit (not shown). The heating unit of the supporting plate 542 can heat the substrate W on the supporting plate 542. The heating unit can generate heat. The heat that is generated by the heating unit may be thermal or cooling. The heat generated by the heating unit can be transmitted to the substrate W on the supporting plate 542. Further, the heat transmitted to the substrate W can heat the processing solution supplied to the substrate W. The heating unit may be a heater and/or a cooling coil. However, the heating unit is not limited thereto and may be modified as well-known devices in various ways.

A plurality of supporting pins 544 is provided. The supporting pins 544 are disposed with predetermined intervals at the edge area of the upper surface of the supporting body 542 and protrude upward from the supporting body 542. The supporting pins 544 are disposed to have entirely a ring shape through a combination thereof. The supporting pins 544 support the edge of the rear face of a substrate W such that the substrate W is spaced a predetermined distance apart from the upper surface of the supporting plate 542.

A plurality of chuck pins 546 is provided. The chuck pins 335 are disposed farther away from the center of the supporting plate 542 than the supporting pins 544. The chuck pins 546 protrude upward from the upper surface of the supporting plate 542. When the supporting plate 542 is rotated, the chuck pins 546 support the side of a substrate W to prevent the substrate W laterally deviating from it proper position. The chuck pins 546 are provided to be able to straightly move between an outer position and an inner position in the radial direction of the supporting plate 542. The outer position is a position farther from the center of the supporting plate 342 than the inner position. When a substrate W is loaded onto or unloaded from the supporting plate 542, the chuck pins 546 are positioned outside, and when a process is performed on a substrate W, the chuck pins 546 are positioned inside. The inner position is a position where the chuck pins 546 and the side of a substrate W come in contact with each other and the outer position is a position where the chuck pins 546 and a substrate W are spaced from each other.

The rotating unit 548, 549 rotates the supporting plate 542. The supporting plate 542 can be rotated around its center axis by the rotating unit 548, 549. The rotating unit 548, 549 includes a supporting shaft 548 and an actuator 549. The upper end of the supporting shaft 548 is fixedly coupled to the underside of the supporting plate 542. According to an embodiment, the supporting shaft 548 may be fixedly coupled to the center of the underside of the supporting plate 542. The actuator 549 provides a driving force to rotate the supporting shaft 548. The supporting shaft 548 is rotated by the actuator 549 and the supporting plate 542 can be rotated with the supporting shaft 548.

The lifting unit 560 straightly moves the processing container 320 in the vertical direction. Since the processing container 520 is moved up and down, the height of the processing container 520 relative to the supporting plate 542 is changed. The processing container 520 moves down such that the supporting plate 542 protrudes upward from the processing container 520 when a substrate W is loaded or unloaded onto or from the supporting plate 542. Further, when a process proceeds, the height of the processing container 520 is adjusted such that a processing solution can flow into the collection tanks 522 and 426, depending on the type of the processing solution supplied to a substrate W. The lifting unit 560 has a bracket 562, a moving shaft 564, and an actuator 566. The bracket 562 is fixedly installed on the outer wall of the processing container 520 and the moving shaft 564 that is moved in the vertical direction by the actuator 566 is fixedly coupled to the bracket 562. Selectively, the lifting unit 560 can move the supporting plate 340 in the vertical direction.

The liquid supply unit 580 can supply a processing solution to substrates W. The processing solution may be an organic solvent, or a chemical or a rinse solution described above. The organic solvent may be isopropyl alcohol (IPA).

The liquid supply unit 580 may include a moving member 581 and a nozzle 589. The moving member 581 moves the nozzle 589 to a process position and a standby position. The process position is a position at which the nozzle 589 faces a substrate W supported on the supporting unit 540. According to an embodiment, the process position is a position at which a processing solution is discharged to the top side of a substrate W. Further, the process position includes a first supply position and a second supply position. The first supply position may be a position closer to the center of a substrate W than the second supply position and the second supply position may be a position including an end of a substrate. Selectively, the second supply position may be an area adjacent to an end of a substrate. The standby position is defined as a position at which the nozzle 589 is outside the process position. According to an example, the standby position may be a position at which the nozzle 589 stands by before a substrate W is processed or after processing is completed.

The moving member 581 includes an arm 582, a supporting shaft 582, and an actuator 584. The supporting shaft 341a is positioned at a side of the processing container 520. The supporting shaft 341a is provided to be rotatable by the actuator 584. The supporting shaft 583 is provided to be movable up and down. The arm 582 is coupled to the upper end of the supporting shaft 583. The arm 582 vertically extends from the supporting shaft 583. The nozzle 589 is coupled to the end of the arm 582. As the supporting shaft 583 is rotated, the nozzle 589 can swing with the arm 582. The nozzle 589 can move to the process position and the standby position by swinging. Selectively, the arm 582 may be provided to be movable forward and backward in the longitudinal direction thereof. When viewed from above, the movement path of the nozzle 589 may coincide with the center axis of a substrate W at the process position.

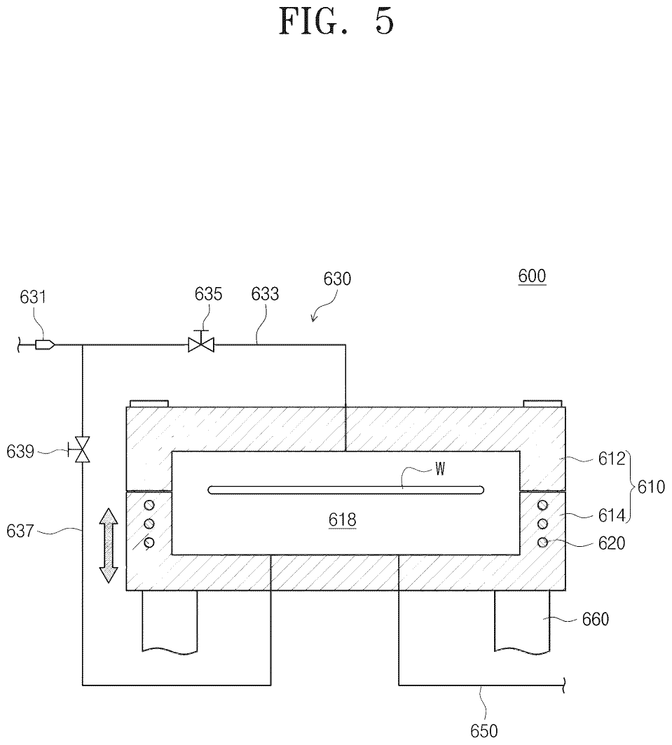

FIG. 5 is a view showing the appearance of an apparatus for treating a substrate provided to a drying chamber of FIG. 1.

Referring to FIG. 5, an apparatus 600 for treating a substrate provided to the drying chamber 370 can remove the residual processing solution on substrates W using a drying fluid G in a supercritical state. The drying chamber 370 may be a supercritical chamber that removes the residual processing solution (e.g., rinse solution or organic solvent) on substrates W using a supercritical fluid. For example, the apparatus 600 for treating a substrate provided to the drying chamber 370 can perform drying that removes the residual organic solvent on substrates W using carbon dioxide (CO₂) in a supercritical state.

The apparatus 600 for treating a substrate provided to the drying chamber 370 may include a body 610, a heating member 620, a fluid supply unit 630, a fluid exhaust unit 650, and a lifting member 660. The body 610 may have an internal space 618 in which substrates W are processed.

The body 610 may provide an internal space 618 in which substrates W are processed. The body 610 may provide an internal space 618 in which substrates W are dried by a drying fluid G in a supercritical state.

The body 610 may include an upper body 612 and a lower body 614. The upper body 612 and the lower body 614 can form the internal space 618 by combining with each other. Substrates W can be supported in the internal space 618. For example, substrates W can be supported by a supporting member (not shown) in the internal space 618. The supporting plate may be configured to support the bottom side of the edge region of substrates W. Any one of the upper body 612 and the lower body 614 may be coupled to the lifting member 660 and moved in the vertical direction. For example, the lower body 614 may be coupled to the lifting member 660 and moved in the vertical direction by the lifting member 660. Accordingly, the internal space 618 of the body 610 can be selectively sealed. It was exemplified in the above example that the lower body 614 is coupled to the lifting member 660 and moved in the vertical direction, but the present disclosure is not limited thereto. For example, the upper body 612 may be coupled to the lifting member 660 and moved in the vertical direction.

The heating member 620 can heat the drying fluid G supplied to the internal space 618. The heating member 620 can change the state of the drying fluid G that is supplied to the internal space 618 into a supercritical state by raising the temperature of the internal space 618 of the body 610.

Further, the heating member 620 can maintain the drying fluid G, which is supplied to the internal space 618 in a supercritical state, in the supercritical state by raising the temperature of the internal space 618 of the body 610.

Further, the heating member 620 may be embedded in the body 610. For example, the heating member 620 may be embedded in any one of the upper body 612 and the lower body 614. For example, the heating member 620 may be provided in the lower body 614. However, the present disclosure is not limited thereto and the heating member 620 may be provided at various positions where it can raise the temperature of the internal space 618. Further, the heating member 620 may be a heater. However, the present disclosure is not limited thereto and the heating member 620 may be modified into various well-known devices that can raise the temperature of the internal space 618.

The fluid supply unit 630 can supply a drying fluid G into the internal space 618 of the body 610. The drying fluid G that is supplied by fluid supply unit 630 may include carbon dioxide (CO₂). The fluid supply unit 630 may include a fluid supply source 631, a first supply line 633, a first supply valve 635, a second supply line 637, and a second supply valve 639.

The fluid supply source 631 can store and/or supply a drying fluid G that is supplied into the internal space 618 of the body 610. The fluid supply source 631 can supply a drying fluid G to the first supply line 633 and/or the second supply line 637. For example, the first supply valve 635 may be installed on the first supply line 633. Further, the second supply valve 639 may be installed on the second supply line 637. The first supply valve 635 and the second supply valve 639 may be of/off valves. Depending on the on/off of the first supply valve 635 and the second supply valve 639, the drying fluid G may selectively flow through the first supply line 633 or the second supply line 637.

In the example described above, it was exemplified that the first supply line 633 and the second supply line 637 are connected to a single fluid supply source 631, but the present disclosure is not limited thereto. For example, a plurality of fluid supply sources 631 may be provided, the first supply line 633 may be connected to any one of the plurality of fluid supply sources 631, and the second supply line 637 may be connected to another one of the fluid supply sources 631.

Further, the first supply line 633 may be an upper supply line that supplies a drying gas over the internal space 618 of the body 610. For example, the first supply line 633 can supply a drying gas downward into the internal space 618 of the body 610. For example, the first supply line 633 may be connected to the upper body 612.

Further, the second supply line 637 may be a lower supply line that supplies a drying gas under the internal space 618 of the body 610. For example, the second supply line 637 can supply a drying gas upward into the internal space 618 of the body 610. For example, the second supply line 637 may be connected to the lower body 614.

The fluid exhaust unit 650 can exhaust a drying fluid G from the internal space 618 of the body 610.

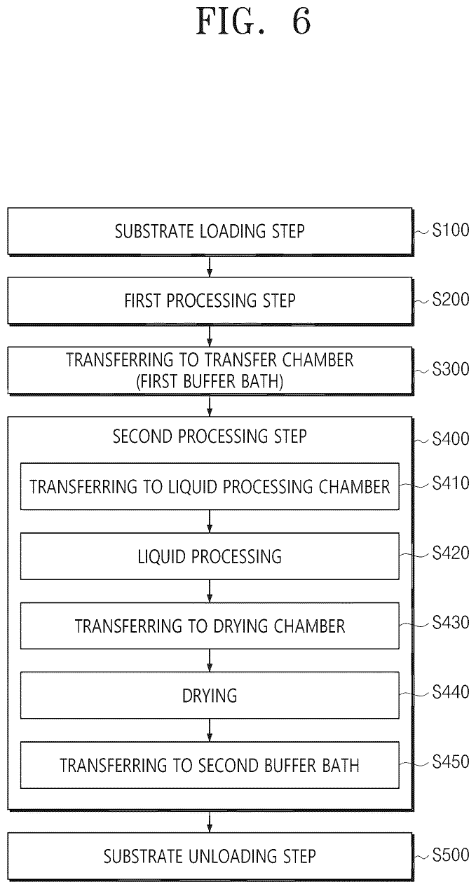

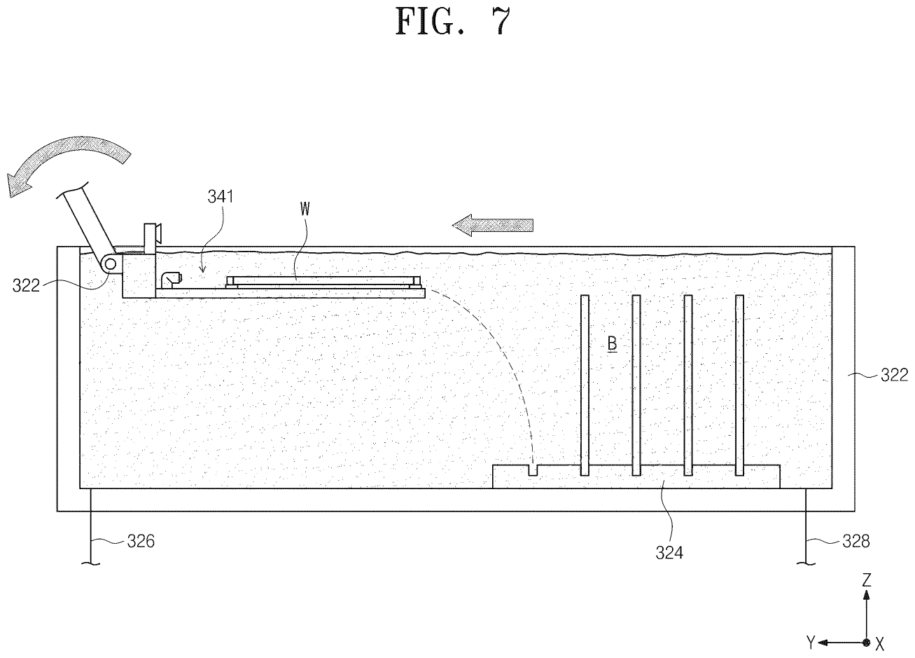

FIG. 6 is a flowchart showing a method for treating a substrate according to an embodiment of the present disclosure and FIG. 7 is a view showing the state in which the first transfer robot of FIG. 1 changes the posture of substrates from a vertical posture to a horizontal posture.

Hereafter, a method for treating a substrate according to an embodiment of the present disclosure is described with reference to FIG. 1 to FIG. 7.

As shown in FIG. 6, the method for treating a substrate according to an embodiment of the present disclosure may include a substrate loading step S100, a first processing step S200, transferring to transfer chamber S300, a second processing step S400, and a substrate unloading step S500. The second processing step S400 may include transferring to a liquid processing chamber S410, performing liquid processing S420, transferring to a drying chamber S430, performing drying S440, and then transferring to a second buffer bath S450.

In the substrate loading step S100, a substrate W that requires to be processed, that is, an unprocessed substrate W can be loaded into the apparatus 10 for treating a substrate. In the substrate loading step S100, a transfer container F can be placed on to the load port unit 100.

The substrate W accommodated in the transfer container F can be unloaded and loaded into an accommodation container C by the index robot 122.

Thereafter, the accommodation container C is rotated around the first direction X by the posture changing unit 124, whereby the posture of the substrate W can be changed. The posture changing unit 124 may have a rotary shaft that can rotate accommodation containers around the first direction X. The posture of a plurality of substrates can be changed at a time by the posture changing unit 124.

The substrate W changed to a vertical posture can be transferred to the first batch processing unit 230 of the first processing unit 200 by the index transfer unit 132.

In the first processing step S200, liquid processing can be performed on the plurality of substrates W in a vertical posture. In the first processing step S200, substrates W can be processed in a bath type. In the first processing step S200, substrates W can be transferred to at least one or more batch processing baths and liquid processing can be performed on the substrates W. The first processing step S200 may be performed in such a manner that preprocessing is performed in the first batch processing unit 230 and post-processing is performed in the second batch processing unit 240 or the third batch processing unit 250.

For example, substrates W transferred to the first batch processing unit 230 can be subjected to liquid processing in the 1-1 batch processing bath 231 and/or the 1-2 batch processing bath 232. Substrate W that has been subjected to liquid processing in the 1-1 batch processing bath 231 and/or the 1-2 batch processing bath 232 can be transferred to and processed in any one processing unit selected from the second batch processing unit 240 or the third batch processing unit 250. In the 1-1 batch processing bath 231, the substrates W can be processed with a chemical such as DSP (an example of a first chemical solution), and in the 1-2 batch processing bath 232, the substrates W can be processed with a chemical such as DHF (an example of a second chemical solution).

For example, if substrates W are transferred to the second batch processing unit 240, the substrates W can first be processed with a chemical including phosphoric acid (an example of a third chemical solution) in the 2-1 batch processing bath 241, and then can be rinsed with a rinse solution including water in the 2-2 batch processing bath 242.

When the first processing step S200 is finished, the substrates W can be transferred to the transfer chamber 310 by the batch transfer unit 210 (S300). For example, the batch transfer unit 210 can lift a plurality of substrates W, which have been rinsed in the batch processing unit 220, in a vertical posture and transfer them to the first buffer bath 320 of the transfer chamber 310. As shown in FIG. 2, the substrates W transferred to the first buffer bath 320 can be stored while being supported by the supporting member 324 provided in the supporting area A of the first buffer bath 320.

When the substrates W are transferred to the transfer chamber 310 of the second processing unit 300 (S300), the second processing step S400 is performed. In the second processing step S400, substrates W can be processed one by one in a horizontal posture. The second processing step S400 may include transferring substrates to a liquid processing chamber S410, performing liquid processing on the substrates S420, transferring the substrates to a drying chamber S430, drying the substrates S440, and then transferring the substrate to a second buffer bath S450.

The first transfer robot 340 can change the substrates W, which are stored in the first buffer bath 320, that is, the substrates W supported in a vertical posture by the supporting member 324, one by one into a horizontal posture and transfer them to the liquid processing chamber 360 (S410). The first transfer robot 340 changes the posture of the substrate W, which are immersed in a processing solution L of the first buffer bath 320, from a vertical posture to a horizontal posture. The hand 341 grips any one substrate W of the substrates W, which are supported in a vertical posture on the supporting member 314, moves the substrate W upward, and moves the substrate W straightly in one direction (e.g., the horizontal direction) while rotating the substrate W around the rotation axis of the rotary shaft 342, whereby it is possible to change the position of the substrate W. In this case, as shown in FIG. 7, the posture of the substrate W can be changed from a vertical posture to a horizontal posture with one end immersed in the processing solution L and drawing a virtual curve (e.g., a truncated parabola).

After changing the posture of the substrate W from the vertical posture to the horizontal posture, the first transfer robot 340 transfers the substrate W to one of the plurality of liquid processing chambers 360 stacked around the transfer chamber 310 (S410).

In this case, in order to maintain the wettability of the substrate W as much as possible (otherwise, water marks can be formed with drying of the substrate W), the posture change of the substrate W is performed while the substrate W is immersed in the processing solution L. Further, since the substrate W changed to a horizontal posture is immediately loaded into the liquid processing chamber 360, the substrate W can maintain its wettability as much as possible without drying during the transfer process.

The liquid processing step S420 can process substrates in a single-wafer type. When substrates W temporarily immersed and stored in the second buffer bath 330 are transferred to the liquid processing chamber 360, the liquid processing S420 can be performed in the liquid processing chamber 360. In the liquid processing step S420, an organic solvent such as IPA can be supplied onto substrates W.

After liquid processing of substrates W is finished, the substrates W can be transferred to the drying chamber. Since the liquid-processed substrates W are in a wet state, the first transfer robot 340 can unload the substrates W from the liquid processing chamber 360 and transfer them to the drying chamber 370 (S430).

The drying step S420 can dry substrates W in a single-wafer type. The drying step S440 can be performed in the drying chamber 370 when the substrates W liquid-processed in the liquid processing step S420 are transferred to the drying chamber 370. The drying S440 can remove residual an organic solvents, wetting liquid, or a processing solution L on substrates W by supplying a processing fluid in a supercritical state (e.g., carbon dioxide in a supercritical state) onto the substrates W.

The second transfer robot 350 can unload dry-state substrates W dried in the drying chamber 360, change the posture of the substrates W from a horizontal posture to a vertical posture, and store them in the second buffer bath 330 (S450).

The process of changing the posture of a substrate W from a horizontal position to a vertical position can be performed in reverse order to the process of the first transfer robot 340 changing the posture of a substrate W from a vertical position to a horizontal position and transferring it to the liquid processing chamber (S410), as described above (see FIG. 7). However, when the first transfer robot 340 changes the posture of a substrate W from a vertical position to a horizontal position, the substrate W, which is immersed in a processing solution L in the first buffer bath 320, is changed from a vertical position to a horizontal position to maintain the wettability of the substrate W. On the other hand, a substrate W unloaded from the drying chamber 360 by the second transfer robot 350 is in a dry state, so there is a difference in that the posture change of a substrate W by the second transfer robot 350 occurs in the air.

Depending on cases, the drying S440 may not be performed in the drying chamber 370, and instead, substrates W may be rapidly rotated in the liquid processing chamber 360 and then dried (so-called spin drying). In this case, the substrates W dried in the liquid processing chamber 360 can be changed to a vertical posture and transferred to and stored in the second buffer bath 330 by the second transfer robot 350 instead of the first transfer robot 340.

In the substrate unloading step S500 that is performed after the second processing step S400, the batch transfer unit 210 transfers the substrates W, which has undergone the second processing step S400, from the second buffer bath 330 to the index chamber 120. Thereafter, the substrates W can be transferred to the transfer container F on the load port unit 110 by the index robot 122, and the transfer container F on the load port unit 110 can be grasped and unloaded from the apparatus 10 for processing a substrate by a transfer device such as an OHT.

As described above, the apparatus 10 for treating a substrate according to an embodiment of the present disclosure includes both a first processing unit 200 for batch processing of substrates

W and a second processing unit 300 for single-wafer processing of substrates W. Further, the second processing unit 300 immerses substrates W, which stand by in a vertical posture in the first buffer bath 320 of the transfer chamber 310, into a processing solution and, in this state, changes the posture of the substrates W to a vertical posture, and immediately transfers them to the process chamber, that is, the liquid processing chamber 360. As a result, the time for which the substrates W are exposed to the air in the vertical posture while being transferred can be minimized. Further, in the interface unit 300, substrates W are exposed to the air in a horizontal posture, so the wettability of the substrates W can be maintained during the transfer process. Accordingly, it is possible to minimize the occurrence of pattern leaning and water marks on substrates during a transfer process.

Further, the present disclosure includes a first transfer robot 340 for transferring substrates in a wet state and a second transfer robot 350 for transferring substrates in a dry state. By transferring substrates in the wet state and substrates in a dry state through different transfer units, respectively, it is possible to minimize reverse contamination of the transfer units due to contaminants such as particles remaining on substrates W and prevent contamination of substrates W in the transfer process.

Further, the present disclosure has a structure in which process chambers are arranged around the transfer chamber 310 and the process chambers can be stacked and arranged. Since the first transfer robot 340 and the second transfer robot 350 disposed in the transfer chamber 310 directly transfer substrates W between the buffer baths 320 and 330 and the process chamber, it is possible to improve the productivity of substrates W. That is, it is possible to increase the throughput of the substrates W.

It should be understood that exemplary embodiments are disclosed herein and other modifications may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present disclosure, and all such modifications that would be obvious to one of ordinary skill in the art are intended to be included within the scope of the accompanying claims.

1. An apparatus for treating a substrate, comprising:
a first processing unit having a batch processing bath that processes a plurality of substrates in a vertical posture in a batch;
a second processing unit disposed adjacent to the first processing unit; and
a transfer unit transferring the plurality of substrates in the vertical posture between the first processing unit and the second processing unit, wherein the second processing unit includes:
a transfer chamber;
a plurality of process chambers disposed around the transfer chamber and processing substrates in a horizontal posture one by one;
a first buffer bath disposed in the transfer chamber and providing an accommodation space in which a plurality of substrates in a vertical posture stands by while being immersed in a processing solution;
a first transfer robot changing the substrates disposed in the first buffer bath from the vertical posture to the horizontal posture, and transferring substrates between the first buffer bath and the process chambers.

2. The apparatus of claim 1, wherein the second processing unit includes:
a second buffer bath disposed in the transfer chamber and storing substrates processed in the process chambers in a vertical posture; and
a second transfer robot unloading substrates processed in the process chambers, changing the substrates from the horizontal posture to the vertical posture, and transferring the substrates to the second buffer bath.

3. The apparatus of claim 2, wherein the batch processing bath and the first buffer bath are arranged side by side in a first direction, and
the transfer unit transfers a plurality of substrates between the batch processing bath and the first buffer bath.

4. The apparatus of claim 3, wherein the processing chamber includes a liquid processing chamber and a drying chamber.

5. The apparatus of claim 1, wherein the posture change of the substrates from the vertical posture to the horizontal posture by the first transfer robot is performed with the substrates immersed in a processing solution retained in the accommodation space of the first buffer bath.

6. The apparatus of claim 3, wherein the first processing unit, the first buffer bath, and the second buffer bath are sequentially arranged in the first direction, and
the first transfer robot and the second transfer robot are disposed between the first buffer bath and the second buffer bath.

7. The apparatus of claim 3, wherein the first transfer robot and the second transfer robot are arranged in a second direction perpendicular to the first direction.

8. The apparatus of claim 2, wherein a hand of the first transfer robot and a hand of the second transfer robot are provided at different heights.

9. The apparatus of claim 8, wherein the process chambers are provided in a polygonal shape when viewed from above.

10. The apparatus of claim 4, further comprising a controller,
wherein the controller controls the first transfer robot to change the substrates disposed in the first buffer bath from the vertical posture to the horizontal posture and transfer the substrates to the liquid processing chamber.

11. The apparatus of claim 10, wherein the controller controls the first transfer robot to unload the substrates liquid-processed in the liquid processing chamber and transfer the substrates to the drying chamber.

12. The apparatus of claim 11, wherein the controller controls the second transfer robot to unload the substrates dried in the drying chamber, change the posture of the substrates from the horizontal posture to the vertical posture, and transfer the substrates to the second buffer bath.

13-16. (canceled)

17. An apparatus for treating a substrate, comprising:
a first processing unit having a batch processing bath that processes a plurality of substrates in a vertical posture in a batch;
a second processing unit disposed adjacent to the first processing unit; and
a transfer unit transferring the plurality of substrates in the vertical posture between the first processing unit and the second processing unit while moving in a first direction,
wherein the second processing unit includes:
a transfer chamber;
a plurality of process chamber disposed around the transfer chamber and processing substrates in a horizontal posture one by one;
a first buffer bath disposed in the transfer chamber and providing an accommodation space in which a plurality of substrates in a vertical posture stands by while being immersed in a processing solution;
a first transfer robot changing the substrates disposed in the first buffer bath from the vertical posture to the horizontal posture, and transferring substrates between the first buffer bath and the process chambers;
a second buffer bath disposed in the transfer chamber and storing substrates processed in the process chambers in a vertical posture; and
a second transfer robot unloading substrates processed in the process chambers, changing the substrates from the horizontal posture to the vertical posture, and transferring the substrates to the second buffer bath,
the processing chambers include a liquid processing chamber and a drying chamber,
the first processing unit, the first buffer bath, and the second buffer bath are sequentially arranged in the first direction, and
the first transfer robot and the second transfer robot are disposed between the first buffer bath and the second buffer bath.

18. The apparatus of claim 17, wherein the posture change of the substrates from the vertical posture to the horizontal posture by the first transfer robot is performed with the substrates immersed in a processing solution retained in the accommodation space of the first buffer bath.

19. The apparatus of claim 17, wherein a hand of the first transfer robot and a hand of the second transfer robot are provided at different heights.

20. The apparatus of claim 17, further comprising
a controller,
wherein the controller
controls the first transfer robot to change the substrates disposed in the first buffer bath from the vertical posture to the horizontal posture and transfer the substrates to the liquid processing chamber,
controls the first transfer robot to unload the substrates liquid-processed in the liquid processing chamber and transfer the substrates to the drying chamber, and
controls the second transfer robot to unload the substrates dried in the drying chamber, change the posture of the substrates from the horizontal posture to the vertical posture, and transfer the substrates to the second buffer bath.
